(19) United States
(12) Patent Application Publication
(10) Pub. No.: US 2017/0358561 A1
(43) Pub. Date: Dec. 14, 2017

(54) LED LEADFRAME AND LED PACKAGING STRUCTURE

(71) Applicant: KAISTAR Lighting (Xiamen) Co., Ltd., Xiamen (CN)

(72) Inventors: Tian He, Xiamen (CN); Zhiwei Huang, Xiamen (CN)

(21) Appl. No.: 15/588,721

(22) Filed: May 8, 2017

(30) Foreign Application Priority Data
Jun. 13, 2016 (CN) 201610411422.7

(51) Int. Cl. H01L 25/16; H01L 33/48; H01L 33/62; H01L 29/866

(52) U.S. Cl. CPC H01L 25/167; H01L 33/62; H01L 25/165; H01L 33/486; H01L 29/866

(57) ABSTRACT

A LED leadframe and a LED packaging structure adopting the same are provided. The LED leadframe includes an insulating substrate, a first electrode pad and a second electrode pad. The insulating substrate is formed with a bowl-shaped die bonding region and a strip-like insulating portion in the bowl-shaped die bonding region. The first and second electrode pads are fixed on the insulating substrate and disposed on a bottom of the die bonding region and whereby are separated by the strip-like insulating portion. The strip-like insulating portion has at least one bend. The structural design of the electrode pads of the LED leadframe makes a size of one of the electrode pads such as the positive electrode pad be available for a bonding machine to perform wire bonding or for placing a Zener diode chip and meanwhile makes the other electrode pad be as large as possible.

### TECHNICAL FIELD

The invention relates to a LED technical field, and more particularly to a LED leadframe and a LED packaging structure.

### DESCRIPTION OF RELATED ART

A conventional light emitting diode (LED) leadframe generally includes an insulating substrate, a positive electrode pad and a negative electrode pad. The insulating substrate is typically disposed with a die bonding region in the middle, the negative electrode pad and the positive electrode pad both are fixed on the insulating substrate and spacedly-disposed at the bottom of the die bonding region, and an area of the negative electrode pad within the die bonding region is larger than an area of the positive electrode pad within the die bonding region. When the LED leadframe is applied in LED chip packaging, a LED chip will be fixed on the negative electrode pad within the die bonding region and further connected to the positive electrode pad and the negative electrode pad by wire bonding.

However, as an area of the conventional positive electrode pad within the die bonding region is overlarge, the LED chips fail to be disposed in the middle of the die bonding region during a LED chip packaging process, which reduces light emitting efficiency of the LED chips. Moreover, since the area of the positive electrode pad within the die bonding region is overlarge, so that the area of the negative electrode pad within the die bonding region is relatively small, and in another aspect LED chips are all disposed on the negative electrode pad, which will reduce heat dissipation effect with respect to the LED chips.

### SUMMARY

Therefore, in order to overcome shortcomings in the prior art, the invention provides a LED leadframe and a LED packaging structure for improving light emitting efficiency as well as heat dissipation effect of chip.

Specifically, the invention provides a LED leadframe including an insulating substrate, a first electrode pad and a second electrode pad. The insulating substrate is formed with a bowl-shaped die bonding region and a strip-like insulating portion located in the bowl-shaped die bonding region. The first electrode pad and the second electrode pad are fixed on the insulating substrate and disposed on a bottom of the die bonding region and whereby are separated by the strip-like insulating portion, the strip-like insulating portion has at least one bend within the bowl-shaped die bonding region.

In an embodiment of the invention, the number of the at least one bend within the bowl-shaped die bonding region is multiple (i.e., more than one).

In an embodiment of the invention, the strip-like insulating portion within the bowl-shaped die bonding region includes two straight-line sections and an arc-shaped section connecting with the two straight-line sections, a side of the first electrode pad adjacent to the strip-like insulating portion within the bowl-shaped die bonding region has an inwardly concave arc-shaped section, and a side of the second electrode pad adjacent to the strip-like insulating portion within the bowl-shaped die bonding region has an outwardly convex arc-shaped section correspondingly.

In an embodiment of the invention, the strip-like insulating portion is consisted by three sequentially connected straight-line sections and is substantially U-shaped.

In an embodiment of the invention, the strip-like insulating portion within the bowl-shaped die bonding region is consisted by two connected straight-line sections with one bend and is substantially L-shaped.

In an embodiment of the invention, a ratio of an area of the first electrode pad to an area of the second electrode pad within the bowl-shaped die bonding region is in a range from 1:3 to 1:5.

In an embodiment of the invention, a width value of the first electrode pad within the bowl-shaped die bonding region is in a range from 0.15 millimeters to 0.3 millimeters.

In an embodiment of the invention, a joint of the first electrode pad and the insulating substrate as well as a joint of the second electrode pad and the insulating substrate are stair-shaped.

Furthermore, a LED packaging structure provided by the embodiment of the invention includes at least a LED chip, a package and a LED leadframe. The at least one LED chip is disposed symmetrically and centrally in the bowl-shaped die bonding region of the LED leadframe, connected with the first electrode pad and the second electrode pad by wire bonding and fixed on the second electrode pad. The package is filled in the bowl-shaped die bonding region and covering the at least one LED chip.

In an embodiment of the invention, the LED packaging structure further includes a Zener diode chip, fixed on the first electrode pad by soldering and connected with the second electrode pad by wire bonding.

It can be known that the structural design of the electrode pads of the LED leadframe according to the embodiments of the invention makes a size of one of the electrode pads such as a positive electrode pad available for a wire bonding machine to bond wires or for placing a Zener diode chip, so that the other electrode pad can be as large as possible, and the LED chip(s) can be distributed symmetrically and centrally in the LED leadframe to achieve objectives of improving light emitting efficiency and heat dissipation effect of the chip(s).

By the following detailed description with reference to accompanying drawings, other aspects and features of the invention will become apparent. However, it should be understood that, the drawings only are for the purpose of explanation and not as limiting the scope of the invention. It also be appreciated that, unless otherwise indicated, the drawings are not necessarily drawn to scale, they are merely trying to conceptually illustrate the structures and procedures described herein.

### BRIEF DESCRIPTION OF THE DRAWINGS

In the following, with reference to accompanying drawings, concrete embodiments of the invention will be described in detail.

FIG. 1 is a perspective structural schematic view of a LED leadframe (with LED chips) according to an embodiment of the invention.

FIG. 2 is a perspective exploded schematic view of the structure shown in FIG. 1.

FIG. 3 is a planar schematic view of the structure shown in FIG. 1.

FIG. 4A is a cross-sectional view taken along the line IVA-IVA in FIG. 3.

FIG. 4B is a cross-sectional view taken along the line IVB-IVB in FIG. 3.

FIGS. 5A-5E are various examples of LED leadframes being applied in LED chip packaging according to embodiments of the invention.

FIG. 6 is a structural planar schematic view of a LED leadframe (with LED chips) according to another embodiment of the invention.

FIG. 7 is a structural planar schematic view of a LED leadframe (with LED chips) according to still another embodiment of the invention.

### DETAILED DESCRIPTION OF PREFERRED EMBODIMENTS

Embodiments of the invention are described in detail with reference to the accompanying drawings as follows to better understand the previously mentioned objectives, features and advantages of the invention.

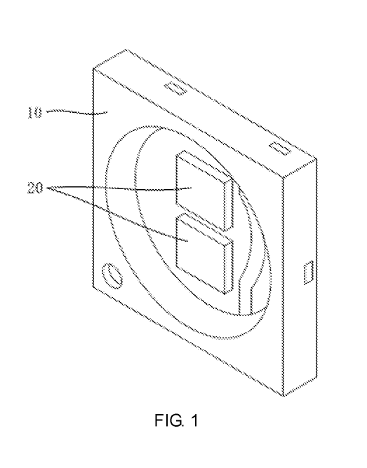

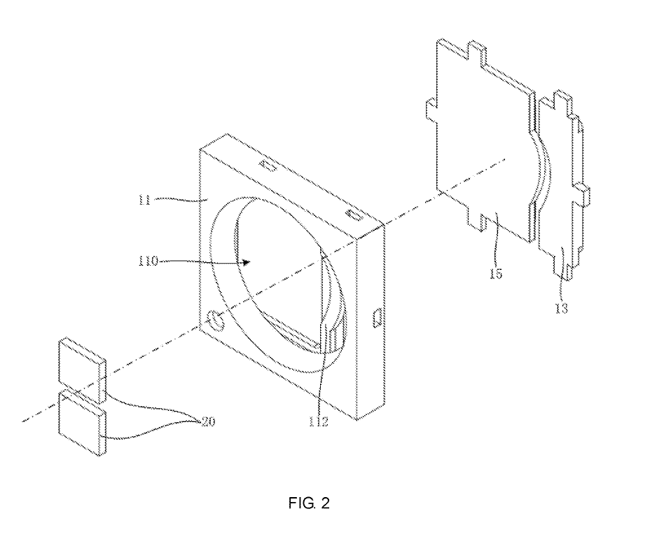

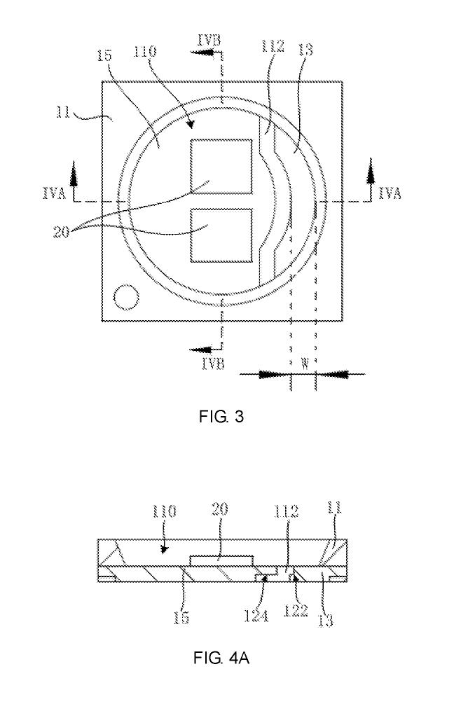

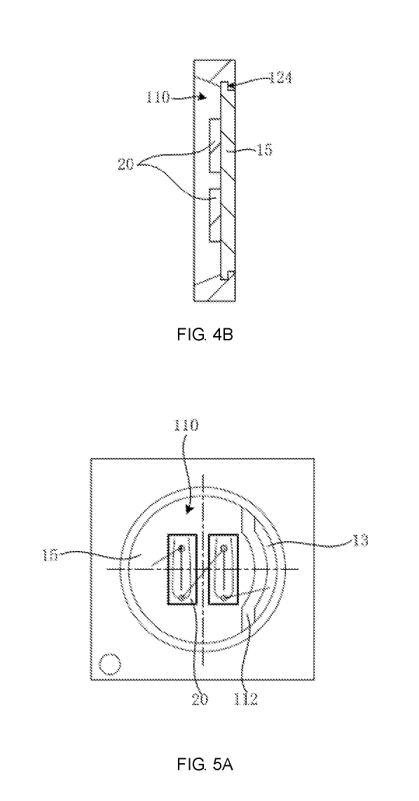

Referring to FIG. 1, FIG. 2, FIG. 3, FIG. 4A and FIG. 4B, a LED leadframe 10 provided by an embodiment of the invention includes an insulating substrate 11, a positive electrode pad 13 and a negative electrode pad 15. The insulating substrate 11 is formed with a bowl-shaped die bonding region 110 in the middle and a strip-like insulating portion 112 in the bowl-shaped die bonding region 110. The negative electrode pad 15 and the positive electrode pad 13 are fixed on the insulating substrate 11 and disposed on a bottom of the die bonding region 110 and whereby are separated by the strip-like insulating portion 112. Typically, the negative electrode pad 15, the positive electrode pad 13 and the insulating substrate 11 are an integrally formed structure by injection molding.

As shown in FIG. 3, the strip-like insulating portion 112 between the positive electrode pad 13 and the negative electrode pad 15 is not a straight/linear strip, which specifically has two bends. To be more specific, the strip-like insulating portion 112 in FIG. 3 is formed by two straight-line sections and an arc-shaped section between the two straight-line sections. A side of the positive electrode pad 13 adjacent to the strip-like insulating portion 112 has an inwardly concave arc-shaped section, and a side of the negative electrode pad 15 adjacent to the strip-like insulating portion 112 has a convex arc-shaped section correspondingly, which means shapes of the positive electrode pad 13 and the negative electrode pad 15 are complementary in the bowl-shaped die bonding region 110. Moreover, a width W of the positive electrode pad 13 within the bowl-shaped die bonding region 110 is in a range of 0.15 millimeters to 0.3 millimeters, which is enough for a wire bonding machine to bond wires or soldering an anti-electrostatic Zener diode chip. A ratio of an area of the positive electrode pad 13 to an area of the negative electrode pad 15 within the bowl-shaped die bonding region 110 is preferably 1:3 to 1:5, and the outwardly convex arc-shaped section of the negative electrode pad 15 can prevent the wire bonding machine from contacting with chips during bonding the Zener diode chip. The area of the positive electrode pad 13 within the die bonding region 110 will be reduced due to the shape design, while the area of the negative electrode pad 15 within the die bonding region 110 is increased correspondingly, the area of the negative electrode pad 15 is far larger than that of the positive electrode pad 13, which can make a LED chip 20 such as a LED chip with a model number 3030 be symmetrically and centrally placed in the bowl-shaped die bonding region 110 of the LED leadframe 10 and fixed on the negative electrode pad 15 when the LED leadframe 10 is applied in LED chip packaging, so as to increase excitation efficiency of fluorescent powders and improve light emitting efficiency of the chips, and the increase of the area of the negative electrode pad 15 within the bowl-shaped die bonding region 110 can assist the LED chip 20 to dissipate heat.

As shown in FIG. 4A and FIG. 4B, a joint 122 of the positive electrode pad 13 and the insulating substrate 11 is designed to be stair-shaped, a joint 124 of the negative electrode pad 15 and the insulating substrate 11 is designed to be stair-shaped as well, so as to extend a path for infiltrating water and improve airtightness.

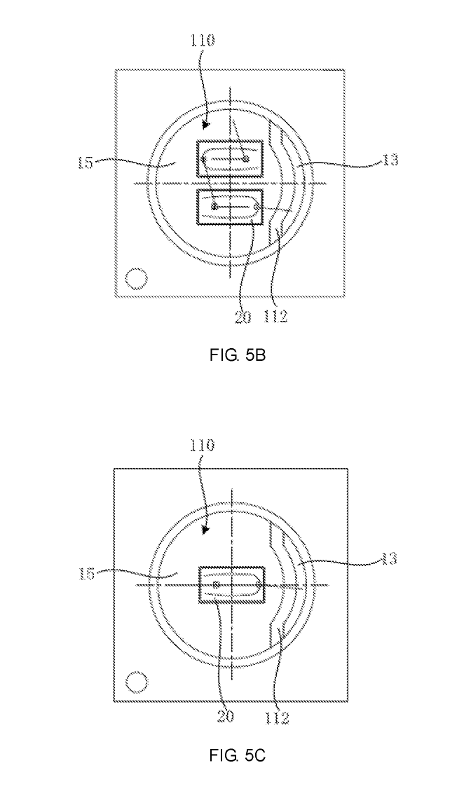

Referring to FIGS. 5A-5E, FIGS. 5A-5E are various examples of LED leadframes applied in LED chip packaging according to embodiments of the invention.

In FIG. 5A, the strip-like insulating portion 112 is formed by two straight-line sections and an arc-shaped section between the two straight-line sections, and the strip-like insulating portion 112 is between the positive electrode pad 13 and the negative electrode pad 15, the two LED chips 20 such as LED chips with a model number 1846 are disposed in the bowl-shaped die bonding region 110 symmetrically and centrally, connected with the positive electrode pad 13 and the negative electrode pad 15 by wire bonding, and fixed on the negative electrode pad 15. Specifically, the two LED chips 20 are arranged transversely and distributed symmetrically with respect to a longitudinal dotted line across a geometrical center (i.e., an intersection point of a transverse dotted line and a longitudinal dotted line in FIG. 5A) of the bowl-shaped die bonding region 110, a geometrical center of each of the LED chips 20 is approximately located at the transverse dotted line across the geometrical center of the bowl-shaped die bonding region 110.

In FIG. 5B, the strip-like insulating portion 112 is formed by two straight-line sections and an arc-shaped section between the two straight-line sections, and the strip-like insulating portion 112 is between the positive electrode pad 13 and the negative electrode pad 15, the two LED chips 20 such as LED chips with a model number 2240 are disposed in the bowl-shaped die bonding region 110 symmetrically and centrally, connected with the positive electrode pad 13 and the negative electrode pad 15 by wire bonding, and fixed on the negative electrode pad 15. Specifically, the two LED chips 20 are arranged longitudinally and distributed symmetrically with respect to a transverse dotted line across a geometrical center (i.e., an intersection point of a transverse dotted line and a longitudinal dotted line in FIG. 5B) of the bowl-shaped die bonding region 110, and a geometrical center of each of the LED chips 20 is approximately located at the longitudinal dotted line across the geometrical center of the bowl-shaped die bonding region 110.

In FIG. 5C, the strip-like insulating portion 112 is formed by two straight-line sections and an arc-shaped section between the two straight-line sections, and the strip-like insulating portion 112 is between the positive electrode pad 13 and the negative electrode pad 15, the LED chip 20 such as the LED chip numbered 2240 is disposed in the bowl-shaped die bonding region 110 symmetrically and centrally, connected with the positive electrode pad 13 and the negative electrode pad 15 by wire bonding, and fixed on the negative electrode pad 15. Specifically, a geometrical center of the LED chip 20 approximately coincides with a geometrical center (i.e., an intersection point of a transverse dotted line and a longitudinal dotted line in FIG. 5C) of the bowl-shaped die bonding region 110, a lengthwise direction of the LED chip 20 is the transverse direction shown in FIG. 5C.

In FIG. 5D, the strip-like insulating portion 112 is formed by two straight-line sections and an arc-shaped section between the two straight-line sections, and the strip-like insulating portion 112 is between the positive electrode pad 13 and the negative electrode pad 15, the LED chip 20 such as the LED chip with a model number 2240 is disposed in the bowl-shaped die bonding region 110 symmetrically and centrally, connected with the positive electrode pad 13 and the negative electrode pad 15 by wire bonding, and fixed on the negative electrode pad 15. Specifically, a geometrical center of the LED chip 20 approximately coincides with a geometrical center (i.e., an intersection point of a transverse dotted line and a longitudinal dotted line in FIG. 5D) of the bowl-shaped die bonding region 110, a lengthwise direction of the LED chip 20 is the longitudinal direction shown in FIG. 5D.

In FIG. 5E, the strip-like insulating portion 112 is formed by two straight-line sections and an arc-shaped section between the two straight-line sections, and the strip-like insulating portion 112 is between the positive electrode pad 13 and the negative electrode pad 15, the two LED chips 20 such as LED chips with a model number F2630 are disposed in the bowl-shaped die bonding region 110 symmetrically and centrally, connected with the positive electrode pad 13 and the negative electrode pad 15 by wire bonding, and fixed on the negative electrode pad 15. Specifically, the two LED chips 20 are arranged longitudinally and distributed symmetrically with respect to a transverse dotted line across a geometrical center (i.e., an intersection point of a transverse dotted line and a longitudinal dotted line in FIG. 5E) of the bowl-shaped die bonding region 110, and a geometrical center of each of the LED chips 20 is approximately located at the longitudinal dotted line across the geometrical center of the bowl-shaped die bonding region 110. Moreover, the positive electrode pad 13 is fixed with an anti-electrostatic Zener diode chip 30 by soldering, and a positive electrode of the Zener diode chip 30 is connected to the negative electrode pad 15 by wire bonding.

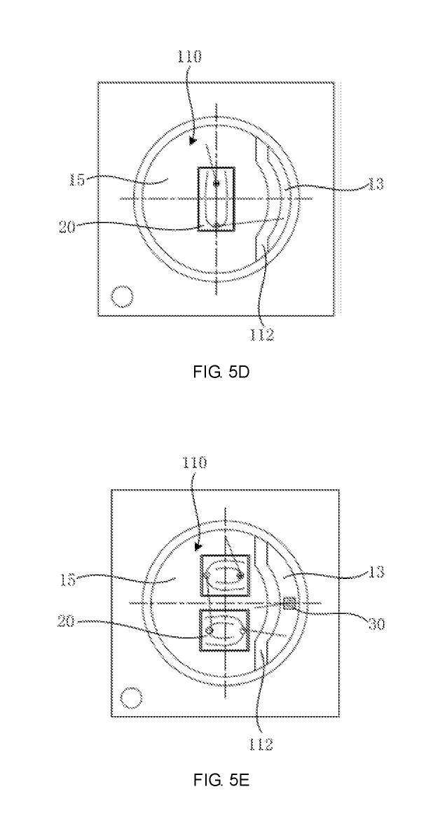

Referring to FIG. 6, in another embodiment of the invention, although the strip-like insulating portion 112 between the positive electrode pad 13 and the negative electrode pad 15 for separation is designed to have two bends, it can be formed by three straight-line sections instead and is substantially U-shaped.

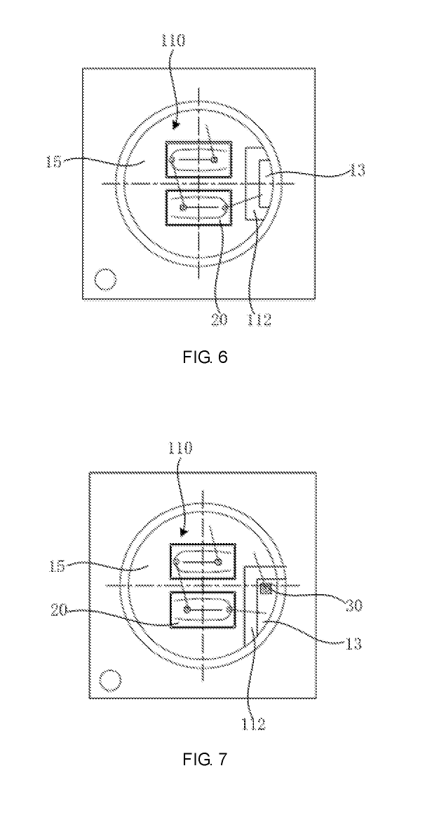

Referring to FIG. 7, in still another embodiment, the strip-like insulating portion 112 between the positive electrode pad 13 and the negative electrode pad 15 for separation can further be designed to have one bend, such as formed by two straight-line sections and is substantially L-shaped.

Finally, an embodiment of the invention further provides a LED packaging structure, which includes the LED leadframe 10 according to any of the embodiments as described above, one or more LED chips 20 disposed in the bowl-shaped die bonding region 110 of the LED leadframe 10 symmetrically and centrally, and a package (not shown in the figures) filled in the bowl-shaped die bonding region 110 that covers each LED chip 20. Each LED chip 20 is fixed on the negative electrode pad 15 and electrically connected with the positive electrode pad 13 as well as the negative electrode pad 15 by wire bonding, the package can be a fluorescent glue such as silicone mixed with fluorescent powders or a silicone with a fluorescent coating, etc.

In summary, the structural design of the electrode pads (the positive electrode pad, the negative electrode pad) of the LED leadframe according to the embodiments of the invention makes a size of one of the electrode pads such as the positive electrode pad available for a bonding machine to bond a wire or for placing a Zener diode chip, so that the other electrode pad can be as large as possible, and the LED chip(s) can be disposed symmetrically and centrally in the LED leadframe to achieve objectives of improving light emitting efficiency and heat dissipation effect of the chip(s). Moreover, it should be understood that the strip-like insulating portion between the positive electrode pad and the negative electrode pad for separation is not restricted to have one or two bends mentioned above, which can have more bends. In addition, the model numbers of the LED chips are not limited as the above model numbers, other model numbers can be adopted as well. The amount of the LED chip(s) disposed in the LED leadframe symmetrically and centrally is/are not limited as one or two as above, which can also be more than two.

The above description illustrates preferred embodiments of the invention rather than any limitation, though the preferred embodiments are disclosed previously, the invention needs not be limited to the disclosed embodiments. For those skilled persons in the art, various modifications and variations can be made according to the concept of the invention. It is intended to cover various modifications and similar arrangements included within the spirit and scope of the appended claims that are to be accorded with the broadest interpretation so as to encompass all such modifications and similar structures.

What is claimed is:

1. A LED leadframe comprising: an insulating substrate, a first electrode pad and a second electrode pad; wherein the insulating substrate is formed with a bowl-shaped die bonding region and a strip-like insulating portion located in the bowl-shaped die bonding region; the first electrode pad and the second electrode pad are fixed on the insulating substrate and disposed on a bottom of the die bonding region and whereby are separated by the strip-like insulating portion, the strip-like insulating portion has at least one bend within the bowl-shaped die bonding region.

2. The LED leadframe according to claim 1, wherein the at least one bend within the bowl-shaped die bonding region is multiple.

3. The LED leadframe according to claim 2, wherein the strip-like insulating portion within the bowl-shaped die bonding region comprises two straight-line sections and an arc-shaped section connecting with the two straight-line sections, a side of the first electrode pad adjacent to the strip-like insulating portion within the bowl-shaped die bonding region has an inwardly concave arc-shaped section, and a side of the second electrode pad adjacent to the strip-like insulating portion within the bowl-shaped die bonding region has an outwardly convex arc-shaped section correspondingly.

4. The LED leadframe according to claim 2, wherein the strip-like insulating portion within the bowl-shaped die bonding region is consisted by three sequentially connected straight-line sections and is substantially U-shaped.

5. The LED leadframe according to claim 1, wherein the strip-like insulating portion within the bowl-shaped die bonding region is consisted by two connected straight-line sections with one bend and is substantially L-shaped.

6. The LED leadframe according to claim 1, wherein a ratio of an area of the first electrode pad to an area of the second electrode pad within the bowl-shaped die bonding region is in a range from 1:3 to 1:5.

7. The LED leadframe according to claim 1, wherein a width of the first electrode pad within the bowl-shaped die bonding region is in a range from 0.15 millimeters to 0.3 millimeters.

8. The LED leadframe according to claim 1, wherein a joint of the first electrode pad and the insulating substrate as well as a joint of the second electrode pad and the insulating substrate are stair-shaped.

9. A LED packaging structure comprising: at least one LED chip, a package and a LED leadframe; the LED leadframe comprising an insulating substrate, a first electrode pad and a second electrode pad; wherein the insulating substrate is formed with a bowl-shaped die bonding region and a strip-like insulating portion in the bowl-shaped die bonding region, the first electrode pad and the second electrode pad are fixed on the insulating substrate and disposed on a bottom of the die bonding region and whereby are separated by the strip-like insulating portion, the strip-like insulating portion has at least one bend within the bowl-shaped die bonding region; the at least one LED chip is centrally and symmetrically disposed in the bowl-shaped die bonding region of the LED leadframe, connected with the first electrode pad and the second electrode pad by wire bonding and fixed on the second electrode pad; the package is filled in the bowl-shaped die bonding region and covering the at least one LED chip.

10. The LED packaging structure according to claim 9, further comprising a Zener diode chip, fixed on the first electrode pad by soldering and connected with the second electrode pad by wire bonding.

11. The LED packaging structure according to claim 9, wherein the number of the at least one bend within the bowl-shaped die bonding region is multiple.

12. The LED packaging structure according to claim 11, wherein the strip-like insulating portion within the bowl-shaped die bonding region comprises two straight-line sections and an arc-shaped section connecting with the two straight-line sections, a side of the first electrode pad adjacent to the strip-like insulating portion within the bowl-shaped die bonding region has an inwardly concave arc-shaped section, and a side of the second electrode pad adjacent to the strip-like insulating portion within the bowl-shaped die bonding region has an outwardly convex arc-shaped section correspondingly.

13. The LED packaging structure according to claim 11, wherein the strip-like insulating portion within the bowl-shaped die bonding region is consisted by three sequentially connected straight-line sections and is substantially U-shaped.

14. The LED packaging structure according to claim 9, wherein the strip-like insulating portion within the bowl-shaped die bonding region is consisted by two connected straight-line sections with one bend and is substantially L-shaped.

15. The LED packaging structure according to claim 9, wherein a ratio of an area of the first electrode pad to an area of the second electrode pad within the bowl-shaped die bonding region is in a range from 1:3 to 1:5.

16. The LED packaging structure according to claim 9, wherein a width value of the first electrode pad within the bowl-shaped die bonding region is in a range from 0.15 millimeters to 0.3 millimeters.

17. The LED packaging structure according to claim 9, wherein a joint of the first electrode pad and the insulating substrate as well as a joint of the second electrode pad and the insulating substrate are stair-shaped.
